(19) United States
(12) Patent Application Publication
(10) Pub. No.: US 2024/0297152 A1
(43) Pub. Date: Sep. 5, 2024

(54) MODULE

(71) Applicant: Murata Manufacturing Co., Ltd., Kyoto-fu (JP)

(72) Inventor: Yoshihito OTSUBO, Nagaokakyo-shi (JP)

(21) Appl. No.: 18/663,782

(22) Filed: May 14, 2024

Related U.S. Application Data
(63) Continuation of application No. PCT/JP2022/037826, filed on Oct. 11, 2022.

(30) Foreign Application Priority Data
Nov. 22, 2021 (JP) 2021-189140

(51) Int. Cl. H01L 25/065; H01L 23/00; H01L 23/498; H01L 23/538; H01L 25/16

(52) U.S. Cl. CPC H01L 25/0657; H01L 23/49811; H01L 23/5385; H01L 24/16; H01L 24/48; H01L 25/16; H01L 2224/16227; H01L 2224/48157

(57) ABSTRACT

A module comprises: a first electronic component having a first component surface and a second component surface; a second electronic component having a third component surface and a fourth component surface; a first substrate having a first substrate surface and a second substrate surface; and a second substrate having a third substrate surface and a fourth substrate surface, the second substrate being disposed so as to overlap the first substrate while being spaced from the first substrate, the first electronic component and the second electronic component being disposed such that the second component surface and the third component surface face each other, at least a portion of the second electronic component being disposed inside an opening, the first electronic component being mounted on the second substrate surface by face bonding, the second electronic component being wire-bonded to the fourth substrate surface using a second connection terminal.

### CROSS REFERENCE TO RELATED APPLICATION

This is a continuation of International Application No. PCT/JP2022/037826 filed on Oct. 11, 2022 which claims priority from Japanese Patent Application No. 2021-189140 filed on Nov. 22, 2021. The contents of these applications are incorporated herein by reference in their entireties.

### BACKGROUND OF THE DISCLOSURE

### Field of the Disclosure

The present disclosure relates to a module.

### Description of the Related Art

U.S. Pat. No. 10,468,384 B2 (PTL 1) discloses a structure in which two substrates are overlapped with each other in a state of being spaced apart from each other and bonded to each other by a conductive pillar, and a component is mounted on one of the two substrates between the substrates.

Japanese Patent Laying-Open No. 2004-134478 (PTL 2) discloses a semiconductor package having a structure in which an interconnection board provided generally at a central portion thereof with a hole is used, a semiconductor chip is disposed in the hole, and an electrode provided on an upper surface of the semiconductor chip and a connection terminal provided on an upper surface of the interconnection board are wire-bonded and their surroundings are sealed with a mold portion. PTL 2 also discloses a configuration in which a plurality of semiconductor packages are stacked, and soldered and thus connected together and a lowermost semiconductor package is mounted on a motherboard via solder.
PTL 1: U.S. Pat. No. 10,468,384 B2
PTL 2: Japanese Patent Laying-Open No. 2004-134478

### BRIEF SUMMARY OF THE DISCLOSURE

In order to reduce a module in area, a structure in which two substrates are overlapped and joined together as described in PTL 1 is effective. While according to the PTL 1 a space is provided between the substrates to accommodate a mounted component in the space between the substrates, for a component mounted on one substrate by wire bonding, the space between the substrates needs to be a sufficiently large space so that the wire does not abut on the other substrate. However, a large space between the substrates is contrary to reduction in height of the module as a whole.

The plurality of semiconductor packages stacked as disclosed in PTL 2 are simply stacked with the same orientation and thus insufficient for reduction in height.

Accordingly, a possible benefit of the present disclosure is to provide a module capable of sufficient reduction in area and height.

In order to achieve the above possible benefit, a module according to the present disclosure comprises: a first electronic component having a first component surface and a second component surface facing away from each other, the first electronic component including a first connection terminal at the first component surface for face bonding; a second electronic component having a third component surface and a fourth component surface facing away from each other, the second electronic component including a second connection terminal at the fourth component surface for wire bonding; a first substrate having a first substrate surface and a second substrate surface facing away from each other; and a second substrate having a third substrate surface and a fourth substrate surface facing away from each other, the second substrate having an opening. The second substrate is disposed such that the second substrate overlaps the first substrate with the third substrate surface facing the first substrate while the second substrate is spaced from the first substrate on the side of the second substrate surface of the first substrate. The first substrate and the second substrate are electrically connected to each other. The first electronic component and the second electronic component are disposed such that the second component surface and the third component surface face each other. At least a portion of the second electronic component is disposed inside the opening. The first electronic component is mounted on the second substrate surface by face bonding using the first connection terminal. The second electronic component is wire-bonded to the fourth substrate surface using the second connection terminal in a position in which the third component surface is directed toward the second substrate surface.

According to the present disclosure, the first substrate and the second substrate are disposed so as to overlap each other and the first electronic component and the second electronic component are disposed so that the second component surface and the third component surface face each other, and the module can thus have a sufficiently reduced area and height.

### BRIEF DESCRIPTION OF THE SEVERAL VIEWS OF THE DRAWINGS

FIG. 1 is a cross section of a module according to a first embodiment of the present disclosure.

FIG. 2 is a cross section of a double-sided populated board prepared for manufacturing the module according to the first embodiment of the present disclosure.

FIG. 3 is a cross section of a wire bonded product populated board prepared for manufacturing the module according to the first embodiment of the present disclosure.

FIG. 4 is a cross section of a module according to a second embodiment of the present disclosure.

FIG. 5 is a cross section of a double-sided populated board prepared for manufacturing the module according to the second embodiment of the present disclosure.

FIG. 6 is a cross section of a wire bonded product populated board prepared for manufacturing the module according to the second embodiment of the present disclosure.

FIG. 7 is a cross section of an intermediate stage for manufacturing the module according to the second embodiment of the present disclosure.

FIG. 8 is a cross section of a module according to a third embodiment of the present disclosure.

FIG. 9 is a cross section of a module according to a fourth embodiment of the present disclosure.

FIG. 10 is a cross section of a module according to a fifth embodiment of the present disclosure.

FIG. 11 is a cross section of a first modification of the module according to the fifth embodiment of the present disclosure.

FIG. 12 is a cross section of a second modification of the module according to the fifth embodiment of the present disclosure.

FIG. 13 is a cross section of a module according to a sixth embodiment of the present disclosure.

FIG. 14 is a cross section of a modification of the module according to the sixth embodiment of the present disclosure.

FIG. 15 is a cross section of a module according to a seventh embodiment of the present disclosure.

FIG. 16 is a cross section of a first modification of the module according to the seventh embodiment of the present disclosure.

FIG. 17 is a cross section of a second modification of the module according to the seventh embodiment of the present disclosure.

### DETAILED DESCRIPTION OF THE DISCLOSURE

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

### First Embodiment

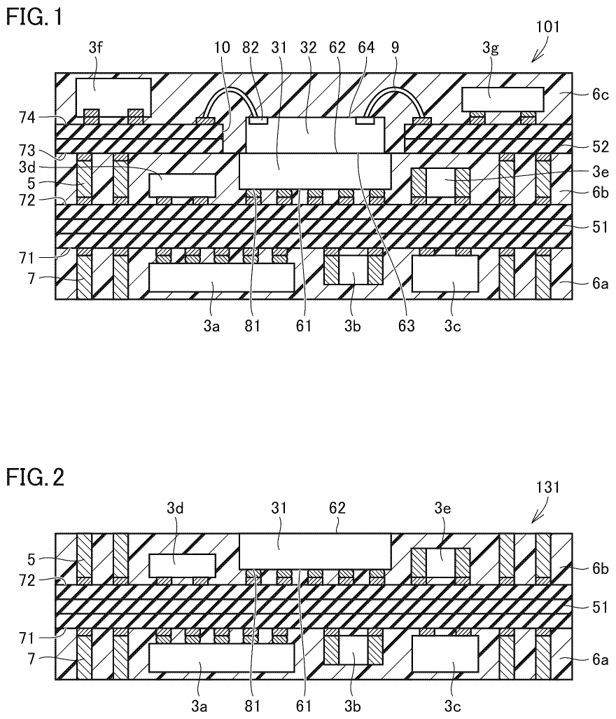

A module according to a first embodiment of the present disclosure will now be described with reference to FIG. 1. FIG. 1 is a cross section of a module 101 according to the present embodiment. Module 101 comprises a first electronic component 31, a second electronic component 32, a first substrate 51, and a second substrate 52. First electronic component 31 has a first component surface 61 and a second component surface 62 facing away from each other. First electronic component 31 includes a first connection terminal 81 at first component surface 61 for face bonding. Second electronic component 32 has a third component surface 63 and a fourth component surface 64 facing away from each other. Second electronic component 32 includes a second connection terminal 82 at fourth component surface 64 for wire bonding. First substrate 51 has a first substrate surface 71 and a second substrate surface 72 facing away from each other. Second substrate 52 has a third substrate surface 73 and a fourth substrate surface 74 facing away from each other. Second substrate 52 has an opening 10. Second substrate 52 is disposed such that the second substrate overlaps first substrate 51 with third substrate surface 73 facing first substrate 51 while the second substrate is spaced from first substrate 51 on the side of second substrate surface 72 of first substrate 51. First substrate 51 and second substrate 52 are electrically connected to each other. First electronic component 31 and second electronic component 32 are disposed so that second component surface 62 and third component surface 63 face each other. At least a portion of second electronic component 32 is disposed inside opening 10. First electronic component 31 is mounted on second substrate surface 72 by face bonding using first connection terminal 81. Second electronic component 32 is wire-bonded to fourth substrate surface 74 using second connection terminal 82 in a position in which third component surface 63 is directed toward second substrate surface 72.

Components 3a, 3b, and 3c are mounted on first substrate surface 71 of first substrate 51. Components 3d and 3e are mounted on second substrate surface 72 of first substrate 51. Components 3f and 3g are mounted on fourth substrate surface 74 of second substrate 52. A columnar conductor is erected on first substrate surface 71 of first substrate 51 as an external terminal 7. A columnar conductor 5 is erected on first substrate surface 72 of first substrate 51. Columnar conductor 5 has an upper end connected to second substrate 52. Components 3a, 3b, and 3c disposed on first substrate 51 on the side of first substrate surface 71 are sealed with sealing resin 6a. External terminal 7 has a lower end exposed at a lower surface of module 101 without being covered with sealing resin 6a. External terminal 7 may have the lower end with the exposed surface covered with a plating film (not shown). Components 3d and 3e disposed on first substrate surface 72 of first substrate 51 are sealed with sealing resin 6b. Components 3f and 3g mounted on fourth substrate surface 74 of second substrate 52 are sealed with sealing resin 6c. A wire 9 interconnecting second connection terminal 82 of second electronic component 32 and fourth substrate surface 74 of second substrate 52 is also sealed with sealing resin 6c.

In the present embodiment, first substrate 51 and second substrate 52 are disposed so as to overlap each other, and the module as a whole can be reduced in area. Furthermore, first electronic component 31 and second electronic component 32 are disposed so that second component surface 62 and third component surface 63 face each other and a gap between first electronic component 31 and second electronic component 32 can be reduced, and the module as a whole can be reduced in height.

As indicated in the present embodiment, second component surface 62 and third component surface 63 preferably abut on each other. By adopting this configuration, a distance between first electronic component 31 and second electronic component 32 can be zeroed, and the module as a whole can further be reduced in height.

As indicated in the present embodiment, second component surface 62 and third component surface 63 may abut on each other in a plane equivalent in level to third substrate surface 73. This configuration allows the following manufacturing method to be adopted for manufacture.

### (Manufacturing Method)

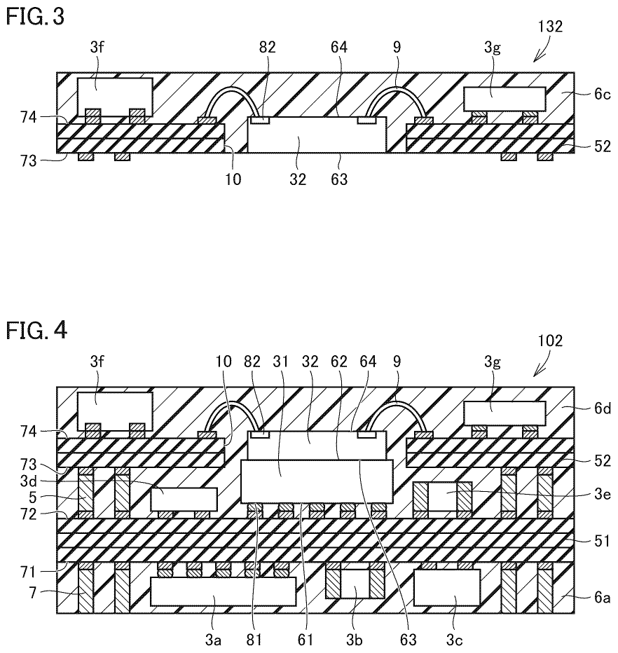

Module 101 according to the present embodiment can be manufactured as follows. Initially, a double-sided populated board 131 shown in FIG. 2 is prepared in advance. Furthermore, a wire bonded product populated board 132 shown in FIG. 3 is prepared. Wire bonded product populated board 132 can be obtained for example by: disposing second substrate 52 having opening 10 on an upper surface of some support layer; disposing second electronic component 32 in opening 10; interconnecting second electronic component 32 and second substrate 52 by wire 9; mounting components 3f and 3g on fourth substrate surface 74 of second substrate 52; introducing sealing resin 6c so as to cover components 3f and 3g; and then removing the support layer. Subsequently, double-sided populated board 131 and wire bonded product populated board 132 are overlapped and thus joined together.

In this case, double-sided populated board 131 and wire bonded product populated board 132 have their respective conductors soldered and thus connected together. Furthermore, sealing resin 6c of wire bonded product populated board 132 may be in a cured state of a stage B and double-sided populated board 131 and wire bonded product populated board 132 may be overlapped and have their respective, thus abutting conductors soldered and thus connected together, and thereafter, sealing resin 6c may be brought to a completely cured state of a stage C to achieve a more firmly joined state. Double-sided populated board 131 may require a polishing process to expose a top surface of first electronic component 31, and accordingly, sealing resin 6b is already in the state of stage C at a point in time when the board is completed as double-sided populated board 131.

Module 101 shown in FIG. 1 can thus be obtained by overlapping and joining double-sided populated board 131 and wire bonded product populated board 132 together. Note that the support layer used herein may be a so-called carrier sheet.

(Level of Plane in which Components Abut on Each Other)

While in the present embodiment is indicated an example in which second component surface 62 and third component surface 63 abut on each other in a plane equivalent in level to third substrate surface 73, this is only one example. Second component surface 62 and third component surface 63 may abut on each other in a plane higher in level than third substrate surface 73. Being “higher in level” as referred to herein means being on an upper side when seen in the position shown in FIG. 1. By adopting this configuration, it is possible to also handle a case in which first electronic component 31 has a large dimension in height. Alternatively, second component surface 62 and third component surface 63 may abut on each other in a plane lower in level than third substrate surface 73. Being “lower in level” as referred to herein means being on a lower side when seen in the position shown in FIG. 1. By adopting this configuration, it is possible to also handle a case in which first electronic component 31 has a small dimension in height.

### Second Embodiment

A module according to a second embodiment of the present disclosure will now be described with reference to FIG. 4. FIG. 4 is a cross section of a module 102 according to the present embodiment. While module 101 described in the first embodiment has sealing resins 6b and 6c separately introduced, module 102 of the present embodiment has sealing resin 6d disposed instead of sealing resins 6b and 6c. Sealing resin 6d also collectively seals components 3d and 3e disposed on second substrate surface 72 of first substrate 51, components 3f and 3g disposed on fourth substrate surface 74 of second substrate 52, and wire 9.

In module 101 described in the first embodiment, second component surface 62 of first electronic component 31 and third component surface 63 of second electronic component 32 abut on each other in the same plane as third substrate surface 73 of second substrate 52, whereas in module 102 according to the present embodiment, second component surface 62 of first electronic component 31 and third component surface 63 of second electronic component 32 abut on each other in a plane higher in level than third substrate surface 73 of second substrate 52. Being “higher in level” as referred to herein means being on an upper side when seen in the position shown in FIG. 4.

The present embodiment can also achieve an effect similar to that of the first embodiment. First electronic component 31 can be disposed partially in opening 10 of second substrate 52 and a distance between first substrate 51 and second substrate 52 can be reduced, and a reduced height can thus be achieved. In particular, when first electronic component 31 has a large thickness, the effect of the present embodiment can be remarkably enjoyed.

### (Manufacturing Method)

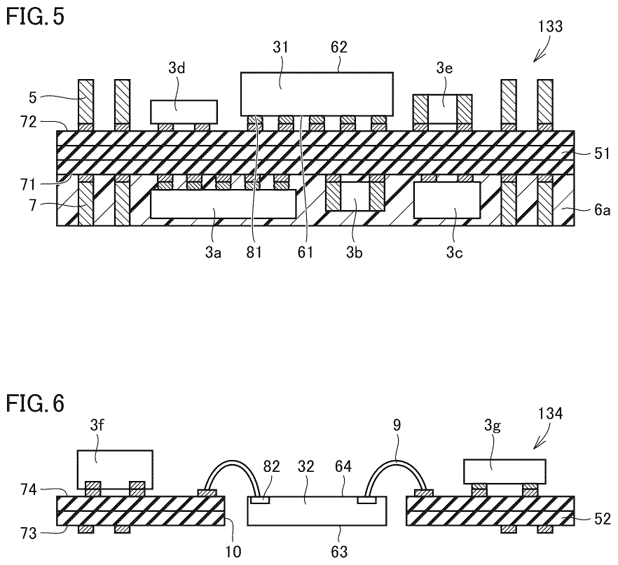

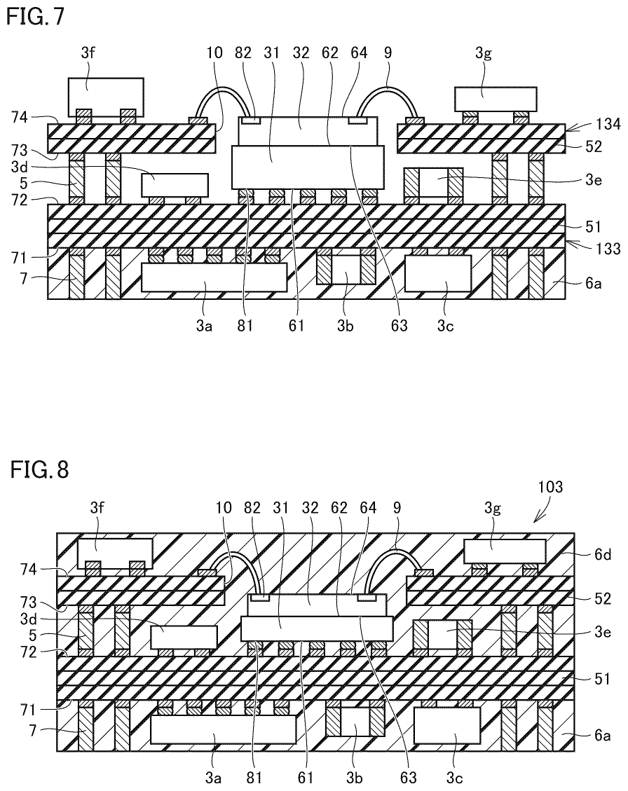

Module 102 according to the present embodiment can be manufactured as follows. Initially, a double-sided populated board 133 shown in FIG. 5 is prepared in advance. Double-sided populated board 133 still does not have sealing resin disposed on first substrate 51 on the side of second substrate surface 72. A wire bonded product populated board 134 shown in FIG. 6 is prepared. Subsequently, double-sided populated board 133 and wire bonded product populated board 134 are overlapped and joined together as shown in FIG. 7. Furthermore, sealing resin is introduced into a gap between first substrate 51 and second substrate 52 and disposed so as to cover components 3f and 3g mounted on second substrate 52 on the side of fourth substrate surface 74 as well as wire 9 to provide sealing resin 6d. Module 102 shown in FIG. 4 can thus be obtained.

### Third Embodiment

A module according to a third embodiment of the present disclosure will now be described with reference to FIG. 8. FIG. 8 is a cross section of a module 103 according to the present embodiment. In module 103, second component surface 62 of first electronic component 31 and third component surface 63 of second electronic component 32 abut on each other in a plane lower in level than third substrate surface 73 of second substrate 52. Being “lower in level” as referred to herein means being on a lower side when seen in the position shown in FIG. 8.

The present embodiment can also achieve an effect similar to that of the first embodiment. Second electronic component 32 can be disposed to partially or entirely protrude below third substrate surface 73 of second substrate 52, and the effect of the present embodiment can be remarkably enjoyed particularly when second electronic component 32 has a large thickness.

### Fourth Embodiment

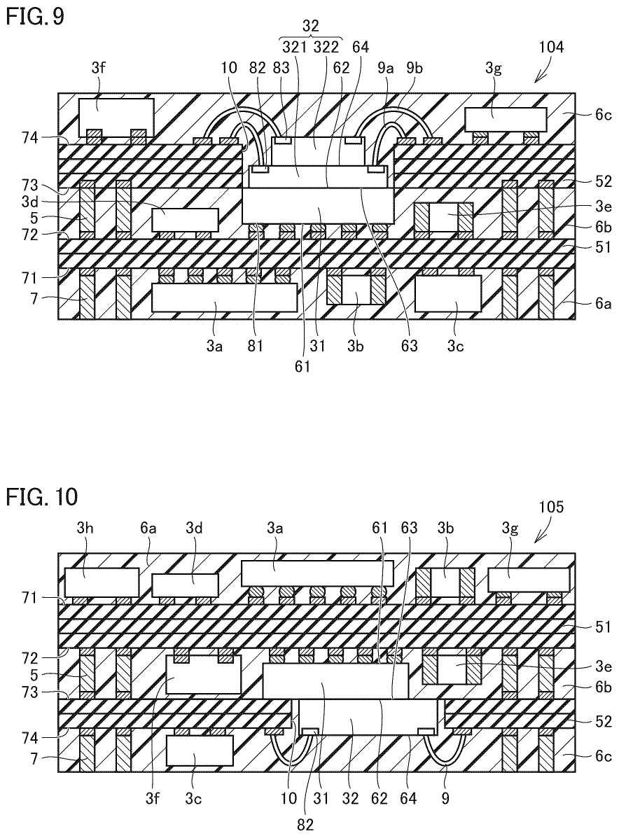

A module according to a fourth embodiment of the present disclosure will now be described with reference to FIG. 9. FIG. 9 is a cross section of a module 104 according to the present embodiment. Second electronic component 32 is a stack of a plurality of electronic component elements. Thus, second electronic component 32 may not necessarily be a single electronic component. Herein, as one example, second electronic component 32 includes electronic component elements 321 and 322. Each of electronic component elements 321 and 322 is an electronic component to be mounted by wire bonding. In the example indicated herein, fourth component surface 64 is an upper surface of electronic component element 321. When each of electronic component elements 321 and 322 is counted as a single electronic component, first electronic component 31, electronic component element 321 of second electronic component 32, and electronic component element 322 of second electronic component 32 are stacked in three stages. Electronic component element 322 is smaller in size than electronic component element 321 when viewed from above. Second connection terminal 82 is provided at a peripheral edge portion of fourth component surface 64 of electronic component element 321. A wire 9a has one end connected to second connection terminal 82. Electronic component element 322 has a lower surface abutting on a portion of fourth component surface 64 of electronic component element 321 other than the peripheral edge portion. A connection terminal 83 is provided at an upper surface of electronic component element 322. A wire 9b has one end connected to connection terminal 83. Wires 9a and 9b have their respective other ends connected to fourth substrate surface 74 of second substrate 52. Electronic component element 322 partially or entirely enters opening 10.

While in FIG. 9 a length of first electronic component 31 in a lateral direction in the figure is shown to be equivalent to that of opening 10 of second substrate 52 in the lateral direction in the figure, this is only one example. The length of first electronic component 31 in the lateral direction in the figure may be longer or shorter than that of opening 10 of second substrate 52 in the lateral direction in the figure. In plan view, first electronic component 31 may have a size equivalent to, larger than, or smaller than that of opening 10.

The present embodiment can also achieve an effect similar to that of the first embodiment. In the present embodiment, electronic components abut on and overlap one another in three stages, and module 104 can be reduced in height while having high functionality. While in the present embodiment has been indicated an example in which second electronic component 32 is a stack of two electronic component elements and as a whole three stages including first electronic component 31 are stacked together, four or more electronic components may be stacked as a whole. When second electronic component 32 is a stack of n electronic component elements, and first electronic component 31 is included, a structure in which n+1 electronic components are stacked together will be provided as a whole.

### Fifth Embodiment

A module according to a fifth embodiment of the present disclosure will now be described with reference to FIG. 10. FIG. 10 is a cross section of a module 105 according to the present embodiment. When module 105 is compared with module 101 described in the first embodiment, the former has first substrate 51 and second substrate 52 having a relationship opposite in position. First substrate 51 has first substrate surface 71 and second substrate surface 72. In the present embodiment, first substrate surface 71 is an upper surface, and second substrate surface 72 is a lower surface. First electronic component 31 is mounted on second substrate surface 72 by face bonding. Second substrate 52 has third substrate surface 73 and fourth substrate surface 74. Third substrate surface 73 is an upper surface, and fourth substrate surface 74 is a lower surface. External terminal 7 is erected on fourth substrate surface 74. When module 105 is compared with module 101 described in the first embodiment, the former has first electronic component 31 and second electronic component 32 having a relationship opposite in position. That is, second electronic component 32 is disposed so as to be in contact with a lower surface of first electronic component 31, or second component surface 62. Second connection terminal 82 provided at fourth component surface 64 of second electronic component 32 and fourth substrate surface 74 of second substrate 52 are connected by wire 9.

The present embodiment can also achieve an effect similar to that of the first embodiment. While in the example shown in FIG. 10 first electronic component 31 and second electronic component 32 overlap each other while being offset in the horizontal direction, the electronic components may overlap each other in such a manner.

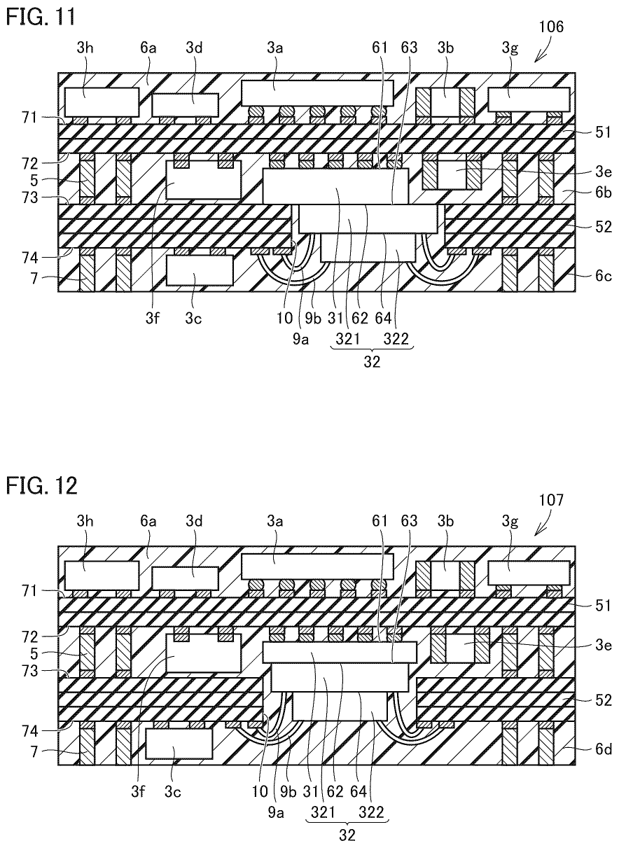

The present embodiment may further be developed to have electronic components stacked in three stages, as in a module 106 shown in FIG. 11. In module 106, first electronic component 31 and second electronic component 32 are stacked on first substrate 51 on the side of second substrate surface 52 downward sequentially. Second electronic component 32 includes electronic component elements 321 and 322 as a plurality of electronic component elements. These electronic component elements are stacked downwards sequentially in the order of electronic component elements 321 and 322. While in module 106 first electronic component 31 and second electronic component 32 abut on each other in the same plane as third substrate surface 73 of second substrate 52, first electronic component 31 and second electronic component 32 may abut on each other in a plane different in level than third substrate surface 73 of second substrate 52, as in a module 107 shown in FIG. 12. While FIG. 12 shows electronic component element 322 having a circuit surface, that is, a lower surface, at the same level as fourth substrate surface 74, electronic component element 322 may have the lower surface on a side closer to a mother board than this position, that is, on a side lower than this position in the figure.

### Sixth Embodiment

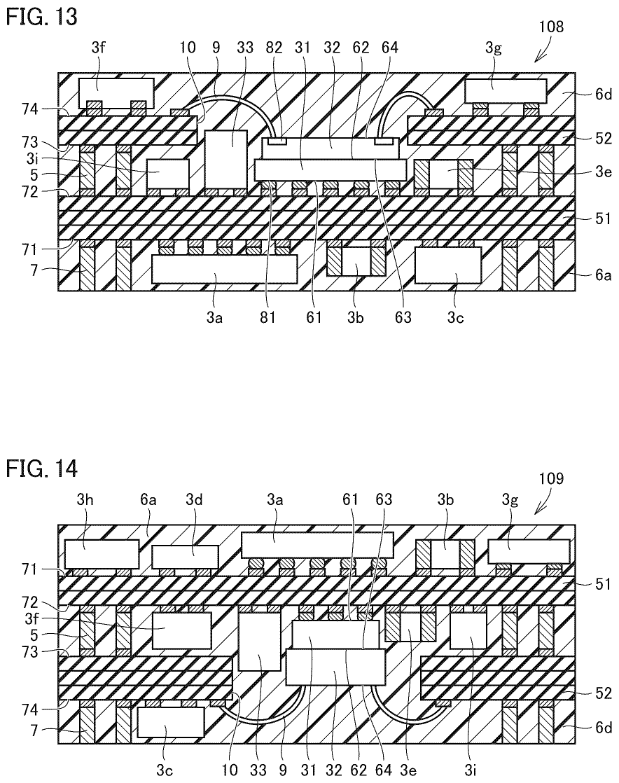

A module according to a sixth embodiment of the present disclosure will now be described with reference to FIG. 13. FIG. 13 is a cross section of a module 108 according to the present embodiment. Although module 108 is similar in configuration to module 101 described in the first embodiment, module 108 has first electronic component 31 and in addition thereto a third electronic component 33 mounted on second substrate surface 72 of first substrate 51. Third electronic component 33 is, for example, an inductor. Furthermore, components 3e and 3i are mounted on second substrate surface 72.

Module 108 comprises third electronic component 33 mounted on second substrate surface 72. Third electronic component 33 as viewed from second substrate surface 72 has a height larger than the size of the gap between second substrate surface 72 and third substrate surface 73. At least a portion of third electronic component 33 enters opening 10. Wire 9 is disposed so as to straddle third electronic component 33.

The present embodiment can also achieve an effect similar to that of the first embodiment. Furthermore, in the present embodiment, third electronic component 33 having a large height is also disposed so as to be accommodated in opening 10 of second substrate 52, and module 108 as a whole can be reduced in height without being affected by third electronic component 33 having the large height.

As indicated in the present embodiment, third electronic component 33 is an inductor, and it is preferable that third electronic component 33 is disposed such that it generates a magnetic flux in a direction perpendicular to second substrate surface 72, a wire having a ground potential is disposed so as to interconnect second electronic component 32 and fourth substrate surface 74, and the wire having the ground potential is disposed so as to straddle an end portion of third electronic component 33 farther away from second substrate surface 72. By adopting this configuration, the inductor, or third electronic component 33, can also be shielded by a wire. At least one wire having the ground potential suffices. A plurality of wires 9 wire-bonding second electronic component 32 may include at least one wire having the ground potential.

Note that module 108 may be turned upside down in configuration to provide such a module as a module 109 shown in FIG. 14. In module 109, third component 33 is mounted on a lower surface of first substrate 51, or second substrate surface 72. Wire 9 is disposed so as to straddle third component 33 below.

### Seventh Embodiment

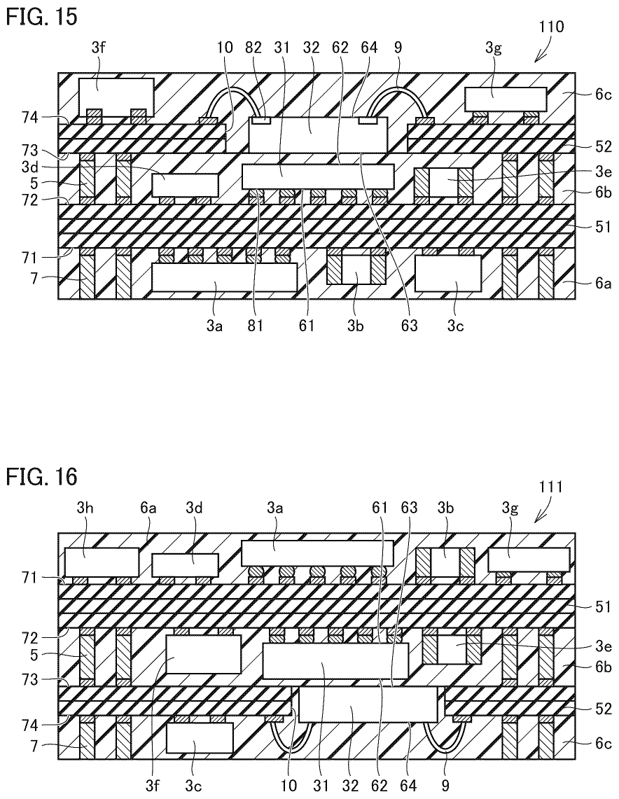

A module according to a seventh embodiment of the present disclosure will now be described with reference to FIG. 15. FIG. 15 is a cross section of a module 110 according to the present embodiment. While module 110 is similar in configuration to module 101 described in the first embodiment, the former differs from the latter in that first electronic component 31 and second electronic component 32 do not abut on each other. That is, in module 110, second component surface 62 of first electronic component 31 and third component surface 63 of second electronic component 32 are spaced from each other and thus fixed relative to each other. In the example indicated here, sealing resin 6b enters between first electronic component 31 and second electronic component 32. For example, some heat insulating material may be interposed between first electronic component 31 and second electronic component 32.

The present embodiment can also achieve an effect similar to that of the first embodiment. Furthermore, if module 110 has some components disposed upside down, such a module as a module 111 shown in FIG. 16 is also conceivable. Module 111 corresponds to the FIG. 10 module 105 with first electronic component 31 and second electronic component 32 spaced from each other.

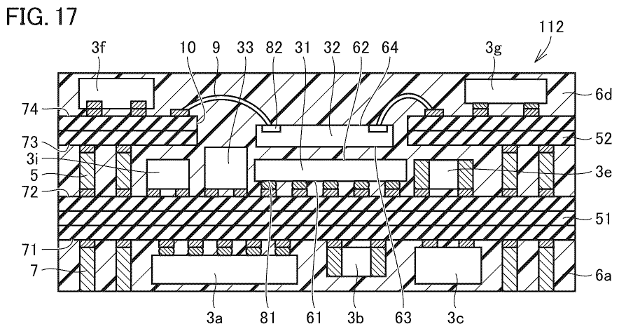

Furthermore, such a module as a module 112 shown in FIG. 17 is also conceivable. Module 112 corresponds to the FIG. 4 module 102 with first electronic component 31 and second electronic component 32 spaced from each other.

Note that a plurality of the above embodiments may be combined as appropriate and employed.

It should be understood that the embodiments disclosed herein are illustrative and non-restrictive in any respect. The scope of the present disclosure is defined by the terms of the claims, and is intended to include any modifications within the meaning and scope equivalent to the terms of the claims.

3a, 3b, 3c, 3d, 3e, 3f, 3g, 3i component, 5 columnar conductor, 6a, 6b, 6c, 6d sealing resin, 7 external terminal, 9, 9a, 9b wire, 10 opening, 31 first electronic component, 32 second electronic component, 33 third electronic component, 51 first substrate, 52 second substrate, 61 first component surface, 62 second component surface, 63 third component surface, 64 fourth component surface, 71 first substrate surface, 72 second substrate surface, 73 third substrate surface, 74 fourth substrate surface, 81 first connection terminal, 82 second connection terminal, 83 connection terminal, 101, 102, 103, 104, 105, 106, 107, 108, 109, 110, 111, 112 module, 131, 133 double-sided populated board, 132, 134 wire bonded product populated board, 321, 322 electronic component element.

1. A module comprising:
a first electronic component having a first component surface and a second component surface facing away from each other, the first electronic component including a first connection terminal at the first component surface for face bonding;
a second electronic component having a third component surface and a fourth component surface facing away from each other, the second electronic component including a second connection terminal at the fourth component surface for wire bonding;
a first substrate having a first substrate surface and a second substrate surface facing away from each other; and
a second substrate having a third substrate surface and a fourth substrate surface facing away from each other, the second substrate having an opening,
the second substrate being disposed such that the second substrate overlaps the first substrate with the third substrate surface facing the first substrate while the second substrate is spaced from the first substrate on a side of the second substrate surface of the first substrate,
the first substrate and the second substrate being electrically connected to each other,
the first electronic component and the second electronic component being disposed such that the second component surface and the third component surface face each other,
at least a portion of the second electronic component being disposed inside the opening,
the first electronic component being mounted on the second substrate surface by face bonding using the first connection terminal,
the second electronic component being wire-bonded to the fourth substrate surface using the second connection terminal in a position in which the third component surface is directed toward the second substrate surface.

2. The module according to claim 1, wherein the second component surface and the third component surface abut on each other.

3. The module according to claim 2, wherein the second component surface and the third component surface abut on each other in a plane higher in level than the third substrate surface.

4. The module according to claim 2, wherein the second component surface and the third component surface abut on each other in a plane lower in level than the third substrate surface.

5. The module according to claim 2, wherein the second component surface and the third component surface abut on each other in a plane equivalent in level to the third substrate surface.

6. The module according to claim 1, wherein the second component surface and the third component surface are spaced from each other and thus fixed relative to each other.

7. The module according to claim 1, wherein the second electronic component is a stack of a plurality of electronic component elements.

8. The module according to claim 1, further comprising a third electronic component mounted on the second substrate surface, wherein
the third electronic component as viewed from the second substrate surface has a height larger than a size of a gap between the second substrate surface and the third substrate surface, and
at least a portion of the third electronic component enters the opening.

9. The module according to claim 8, wherein the third electronic component is an inductor, and disposed such that the third electronic component generates a magnetic flux in a direction perpendicular to the second substrate surface, and a wire having a ground potential is disposed so as to interconnect the second electronic component and the fourth substrate surface, the wire having the ground potential being disposed so as to straddle an end portion of the third electronic component farther away from the second substrate surface.

10. The module according to claim 2, wherein the second electronic component is a stack of a plurality of electronic component elements.

11. The module according to claim 3, wherein the second electronic component is a stack of a plurality of electronic component elements.

12. The module according to claim 4, wherein the second electronic component is a stack of a plurality of electronic component elements.

13. The module according to claim 5, wherein the second electronic component is a stack of a plurality of electronic component elements.

14. The module according to claim 6, wherein the second electronic component is a stack of a plurality of electronic component elements.

15. The module according to claim 2, further comprising a third electronic component mounted on the second substrate surface, wherein
the third electronic component as viewed from the second substrate surface has a height larger than a size of a gap between the second substrate surface and the third substrate surface, and
at least a portion of the third electronic component enters the opening.

16. The module according to claim 3, further comprising a third electronic component mounted on the second substrate surface, wherein
the third electronic component as viewed from the second substrate surface has a height larger than a size of a gap between the second substrate surface and the third substrate surface, and
at least a portion of the third electronic component enters the opening.

17. The module according to claim 4, further comprising a third electronic component mounted on the second substrate surface, wherein
the third electronic component as viewed from the second substrate surface has a height larger than a size of a gap between the second substrate surface and the third substrate surface, and
at least a portion of the third electronic component enters the opening.

18. The module according to claim 5, further comprising a third electronic component mounted on the second substrate surface, wherein
the third electronic component as viewed from the second substrate surface has a height larger than a size of a gap between the second substrate surface and the third substrate surface, and
at least a portion of the third electronic component enters the opening.

19. The module according to claim 6, further comprising a third electronic component mounted on the second substrate surface, wherein
the third electronic component as viewed from the second substrate surface has a height larger than a size of a gap between the second substrate surface and the third substrate surface, and
at least a portion of the third electronic component enters the opening.

20. The module according to claim 7, further comprising a third electronic component mounted on the second substrate surface, wherein
the third electronic component as viewed from the second substrate surface has a height larger than a size of a gap between the second substrate surface and the third substrate surface, and
at least a portion of the third electronic component enters the opening.
